(19) United States
(12) Patent Application Publication
(10) Pub. No.: US 2024/0290626 A1
(43) Pub. Date: Aug. 29, 2024

(54) METHOD OF MANUFACTURING SEMICONDUCTOR DEVICE

(71) Applicant: SAMSUNG ELECTRONICS CO., LTD., SUWON-SI (KR)

(72) Inventors: Heejae Chae, Suwon-si (KR); Taejin Park, Suwon-si (KR); Hyunjin Lee, Suwon-si (KR); Hosang Lee, Suwon-si (KR); Yun Choi, Suwon-si (KR)

(21) Appl. No.: 18/587,326

(22) Filed: Feb. 26, 2024

(30) Foreign Application Priority Data
Feb. 27, 2023 (KR) 10-2023-0026184

(51) Int. Cl. H01L 21/308; H01L 21/027; H01L 21/311; H10B 12/00

(52) U.S. Cl. CPC H01L 21/3086; H01L 21/0274; H01L 21/31144; H10B 12/50

(57) ABSTRACT

A method of manufacturing a semiconductor device includes forming an etch target layer in a surface of a cell region comprising a cell center region and a cell edge region surrounding the cell center region, forming an edge mask pattern on the surface of the cell edge region through a quadruple patterning process on the etch target layer, and forming a plurality of center mask patterns spaced apart from each other on the cell center region, and forming a first etch pattern on the cell edge region by etching the etch target layer by using the edge mask pattern and the plurality of center mask patterns as etch masks and forming a plurality of second etch patterns spaced apart from each other on the cell center region.

### CROSS-REFERENCE TO RELATED APPLICATION

This application is based on and claims priority under 35 U.S.C. § 119 to Korean Patent Application No. 10-2023-0026184, filed on Feb. 27, 2023, in the Korean Intellectual Property Office, the disclosure of which is incorporated by reference herein in its entirety.

### BACKGROUND

The inventive concept relates to a method of manufacturing a semiconductor device, and more particularly, to a method of manufacturing a semiconductor device capable of forming a uniform fine pattern (or a fine etch pattern) in a cell region.

As the degree of integration of semiconductor devices, for example, memory devices, has increased, it has become more difficult to form fine patterns (or fine etch patterns) on semiconductor substrates. In addition, it has become more difficult to form a uniform fine pattern (or fine etch pattern) in a certain region, for example, a cell region, of a semiconductor device as a pattern width is decreased.

### SUMMARY

The inventive concept provides a method of manufacturing a semiconductor device capable of forming a uniform fine pattern (or a fine etch pattern) in a cell region.

According to an aspect of the inventive concept, there is provided a method of manufacturing a semiconductor device including forming an etch target layer within a cell region including a cell center region and a cell edge region surrounding the cell center region, forming an edge mask pattern on the surface of the cell edge region through a quadruple patterning process on the etch target layer, and forming a plurality of center mask patterns spaced apart from each other on the cell center region, and forming a first etch pattern on the cell edge region by etching the etch target layer by using the edge mask pattern and the plurality of center mask patterns as etch masks and forming a plurality of second etch patterns spaced apart from each other on the cell center region.

According to another aspect of the inventive concept, there is provided a method of manufacturing a semiconductor device including forming an etch target layer on a surface of a cell region comprising a cell center region and a cell edge region surrounding the cell center region; sequentially forming a first hard mask layer and a second hard mask layer on the etch target layer;
simultaneously forming a plurality of sacrificial patterns spaced apart from each other on the second hard mask layer of the cell edge region and forming a plurality of first spacers spaced apart from each other on the second hard mask layer of the cell center region; forming a protection pattern on the plurality of sacrificial patterns of the cell edge region and between the plurality of sacrificial patterns; simultaneously forming a second edge hard mask pattern on the cell edge region and a plurality of second center hard mask patterns spaced apart from each other on the cell center region by etching the second hard mask layer using the protection pattern and the plurality of first spacers as an etch mask; removing the protection pattern from the cell edge region; forming a second spacer insulating layer between the plurality of second center hard mask patterns of the cell center region; simultaneously forming a plurality of second spacers spaced apart from each other by etching the second spacer insulating layer and removing the plurality of second center hard mask patterns between the plurality of second spacers; simultaneously forming an edge mask pattern on the cell edge region by etching the first hard mask layer using the second edge hard mask pattern as an etch mask and forming a plurality of center mask patterns spaced apart from each other on the cell center region using the plurality of second spacers as an etch mask; and forming a first etch pattern on the cell edge region by etching the etch target layer by using the edge mask pattern and forming a plurality of second etch patterns spaced apart from each other on the cell center region using the plurality of center mask patterns as an etch mask.

According to another aspect of the inventive concept, there is provided a method of manufacturing a semiconductor device including forming an etch target layer in an entire surface of a cell region including a cell center region and a cell edge region surrounding the cell center region, sequentially forming a first hard mask layer and a second hard mask layer on the etch target layer, simultaneously forming a plurality of sacrificial patterns spaced apart from each other on the second hard mask layer of the cell edge region and forming a plurality of first spacers spaced apart from each other on the second hard mask layer of the cell center region, forming a protection pattern filling inner walls and surfaces of the plurality of sacrificial patterns of the cell edge region and between the plurality of sacrificial patterns, simultaneously forming a second edge hard mask pattern on the cell edge region by etching the second hard mask layer by using the protection pattern and the plurality of first spacers as an etch mask and forming a plurality of second center hard mask patterns spaced apart from each other on the cell center region, simultaneously forming a separation pattern between the plurality of sacrificial patterns of the cell edge region and forming a spacer insulating layer between the plurality of second center hard mask patterns of the cell center region, forming a filling layer filling between the plurality of sacrificial patterns and the plurality of second center hard mask patterns on the separation pattern and the spacer insulating layer, removing the separation pattern formed between the plurality of sacrificial patterns of the cell edge region, removing the filling layer of the cell edge region and the cell center region, simultaneously forming a plurality of second spacers spaced apart from each other by etching the spacer insulating layer between the plurality of second center hard mask patterns and removing the plurality of second center hard mask patterns between the plurality of second spacers, simultaneously forming an edge mask pattern on the cell edge region by etching the first hard mask layer by using the plurality of second center hard mask patterns and the plurality of second spacers as an etch mask, and forming a plurality of center mask patterns spaced apart from each other on the cell center region, and forming a first etch pattern on the cell edge region by etching the etch target layer by using the edge mask pattern and the plurality of center mask patterns as an etch mask and forming a plurality of second etch patterns spaced apart from each other on the cell center region.

### BRIEF DESCRIPTION OF THE DRAWINGS

Embodiments will be more clearly understood from the following detailed description taken in conjunction with the accompanying drawings in which:

FIG. 1 is a plan view of a semiconductor device, according to an embodiment;

FIGS. 2A to 16B are diagrams for explaining a method of manufacturing a semiconductor device, according to an embodiment;

FIG. 17 is a block diagram illustrating a storage device including a semiconductor device, according to an embodiment;

FIG. 18 is a block diagram illustrating an electronic device including a semiconductor device, according to an embodiment; and

FIG. 19 is a schematic diagram illustrating a system including a semiconductor device, according to an embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

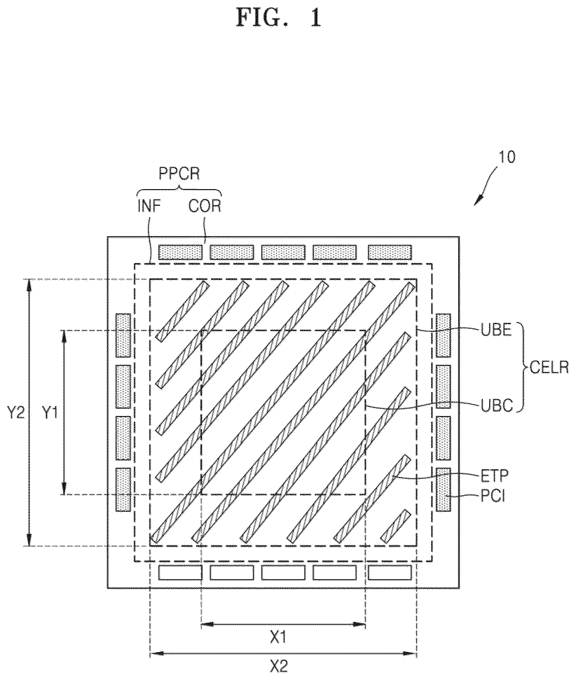

FIG. 1 is a plan view of a semiconductor device according to an embodiment.

Specifically, a semiconductor device 10 may include a cell region CLER and a peripheral circuit region PPCR surrounding the cell region CELR in a plan view. The cell region CLER may include a cell center region UBC and a cell edge region UBE surrounding the cell center region UBC in the plan view. The cell center region UBC and the cell edge region UBE may be referred to as a unit block center region and a unit block edge region, respectively.

In various embodiments, etch patterns ETP (also referred to simply as patterns) may be uniformly disposed on the cell region CELR, where the etch patterns ETP may be uniformly disposed on the cell center region UBC and the cell edge region UBE. The etch patterns ETP may be uniformly formed on the cell edge region UBE without damage. In some embodiments, the etch patterns ETP may be active patterns. The shape of each of the etch patterns ETP of FIG. 1 is shown as an example, and the inventive concept is not limited thereto.

In various embodiments, the cell region CELR may have a length X2 in a horizontal direction (X direction) and a length Y2 in a vertical direction (Y direction), respectively. The length X2 and the length Y2 may be several millimeters (mm) to several tens of mm. In the cell region CELR, the cell center region UBC may have a length X1 in the horizontal direction and a length Y1 in the vertical direction, respectively. A region of the cell region CELR excluding the cell center region UBC may be the cell edge region UBE.

In various embodiments, a width of the cell edge region UBE may be less than or equal to 5% of a length of the cell region CELR. For example, the width of the cell edge region UBE may be calculated from the lengths, X2−X1, which is obtained by subtracting the length X1 of the cell center region UBC in the horizontal direction (X direction) from the length X2 of the cell region CELR in the horizontal direction (X direction). The length X2−X1 may be less than or equal to 5% of the length X1. The width of the cell edge region UBE may be a width calculated from the lengths, Y2−Y1, which is obtained by subtracting the length Y1 of the cell center region UBC in the vertical direction (Y direction) from the length Y2 of the cell region CELR in the vertical direction (Y direction). The width, Y2-Y1, may be less than or equal to 5% of the length Y1.

In various embodiments, the peripheral circuit region PPCR may include an interface region INF surrounding the cell region CELR and a core region COR surrounding the interface region INF in the plan view. A peripheral circuit PCI may be disposed in the core region COR, where the peripheral circuit PCI may be outside the interface region INF.

In various embodiments, the semiconductor device 10 may be a memory device. Accordingly, the cell region CELR described above may be a memory cell region. The memory device may be a volatile memory device such as Dynamic Random Access Memory (DRAM) or Static Random Access Memory (SRAM), or may be a non-volatile memory device such as Phase-change Random Access Memory (PRAM), Magnetoresistive Random Access Memory (MRAM), Ferroelectric Random Access Memory (FeRAM), or Resistive Random Access Memory (RRAM).

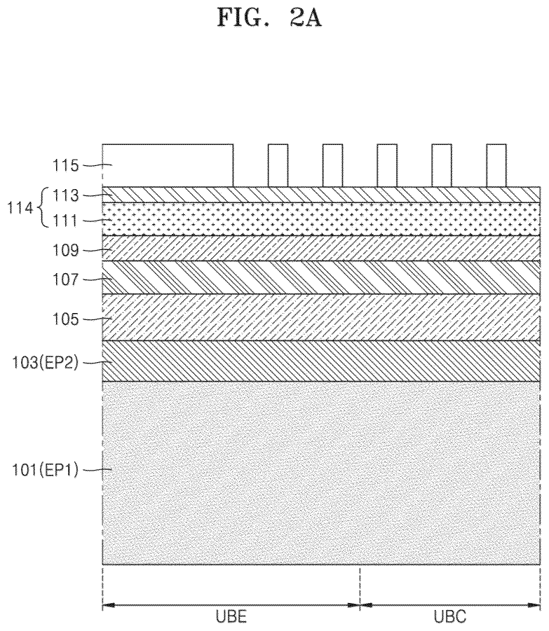

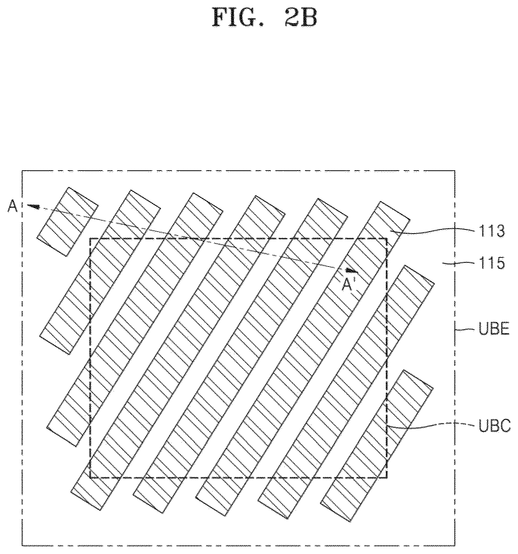

FIGS. 2A to 16B are diagrams for explaining a method of manufacturing a semiconductor device according to an embodiment.

Specifically, FIGS. 2A, 3A, 4A, 5A, 6A, 7A, 8A, 9A, 10A, 11A, 12A, 13A, 14A, 15A, and 16A are cross-sectional views of the cell region CELR of the semiconductor device 10 of FIG. 1, and FIGS. 2B, 3B, 4B, 5B, 6B, 7B, 8B, 9B, 10B, 11B, 12B, 13B, 14B, 15B, and 16B are plan views of the cell region CELR of the semiconductor device 10 of FIG. 1. More, specifically, FIGS. 2A, 3A, 4A, 5A, 6A, 7A, 8A, 9A, 10A, 11A, 12A, 13A, 14A, 15A, and 16A are cross-sectional views taken along A-A′ of FIGS. 2B, 3B, 4B, 5B, 6B, 7B, 8B, 9B, 10B, 11B, 12B, 13B, 14B, 15B, and 16B, respectively.

Referring to FIGS. 2A and 2B, a pad insulating layer 103, a first hard mask layer 105, a second hard mask layer 107, a third hard mask layer 109, a sacrificial layer 114, and a first photoresist pattern 115 may be sequentially formed on a semiconductor substrate 101.

The semiconductor substrate 101 may include the cell center region UBC and the cell edge region UBE. The first photoresist pattern 115 may be formed using a photolithography process. As shown in FIG. 2B, the second sacrificial layer 113 of the sacrificial layer 114, may be exposed by the first photoresist pattern 115.

The pad insulating layer 103 and the semiconductor substrate 101 may be respectively etch target layers EP2 and EP1. In various embodiments, the pad insulating layer 103 may be a second etch target layer EP2. In some embodiments, the semiconductor substrate 101 may be a first etch target layer EP1. The pad insulating layer 103 (the second etch target layer) is shown to be formed only in the cell center region UBC and the cell edge region UBE, but may also be formed in the peripheral circuit region PPCR of FIG. 1.

The plurality of layers stacked on the semiconductor substrate 101 and the pad insulating layer 103, for example, the first hard mask layer 105, the second hard mask layer 107, the third hard mask layer 109, the sacrificial layer 114, and the first photoresist pattern 115, may be used as a mask for forming patterns on the etch target layers EP2 and EP1 or may be layers for forming a mask.

The first to third hard mask layers 105, 107, and 109 may include various film materials according to materials of the etch target layers EP2 and EP1, where the etch target layers EP2 and EP1 can be selectively etched. In some embodiments, the third hard mask layer 109 may not be formed.

In various embodiments, each of the first to third hard mask layers 105, 107, and 109 may include a material having an etch selectivity different from that of a lower layer located therebelow. The etch selectivity may be a ratio of an etch rate of one layer to an etch rate of another layer under a specific etch condition. For example, the second hard mask layer 107 may include a material layer having an etch selectivity compared to the first hard mask layer 105.

In some embodiments, each of the first to third hard mask layers 105, 107, and 109 may include at least one of a silicon-containing material such as silicon oxide (SiO₂), silicon oxynitride (SiON), silicon nitride (Si₃N₄), or polysilicon, a carbon-containing material including a hydrocarbon compound or a derivative thereof, such as an amorphous carbon layer (ACL), or a spin-on hardmask (SOH), a metal, or an organic material.

In various embodiments, the first hard mask layer 105 may include polysilicon, the second hard mask layer 120 may include a carbon-containing material, such as the ACL, and the third hard mask layer 130 may include at least one of silicon oxide (SiO₂) or silicon oxynitride (SiON).

The first to third hard mask layers 105, 107, and 109 may be formed by a process such as atomic layer deposition (ALD), chemical vapor deposition (CVD), or spin coating, and a bake process or a hardening process may be added according to the material.

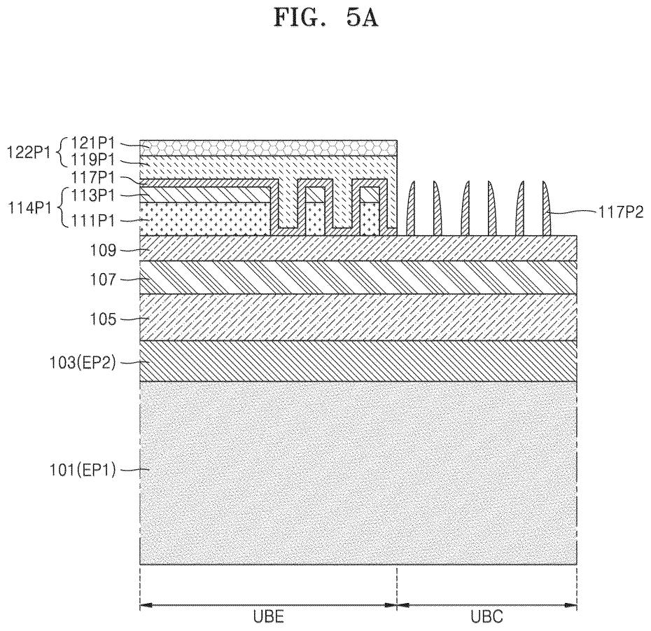

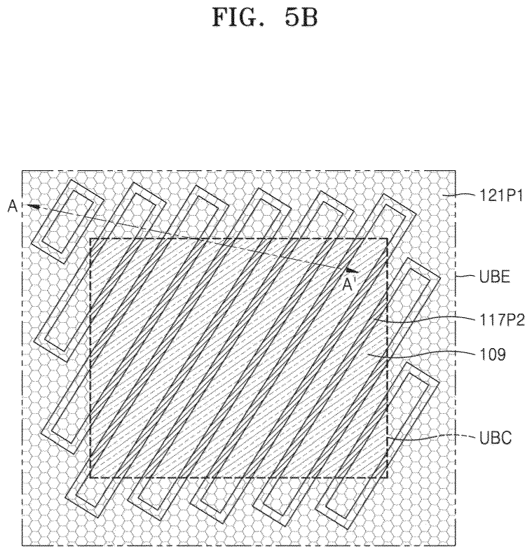

The sacrificial layer 114 may include a first sacrificial layer 111 and a second sacrificial layer 113. The sacrificial layer 114 may be provided to form first spacers 117P2 of FIGS. 5A and 5B in a subsequent process. The second sacrificial layer 113 may be formed to have a relatively smaller thickness than that of the first sacrificial layer 111, but is not limited thereto.

The first and second sacrificial layers 111 and 113 may include materials having different etch selectivities. For example, the first sacrificial layer 111 may include a carbon-containing material, such as Spin-On Hardmask (SOH), and the second sacrificial layer 113 may include silicon oxynitride (SiON).

An antireflection layer may be further formed on the second sacrificial layer 113, and may provide antireflection functionality during a subsequent photolithography process. The antireflection layer may include an organic material or an inorganic material. In some embodiments, the second sacrificial layer 113 may function as the antireflection layer.

Within the scope of the inventive concept, constituent materials of the first to third hard mask layers 105, 107, and 109, and the first and second sacrificial layers 111 and 113 are not limited to those mentioned above, and may be selected as materials having different etch selectivities with respect to a certain etch condition between adjacent layers in each layer.

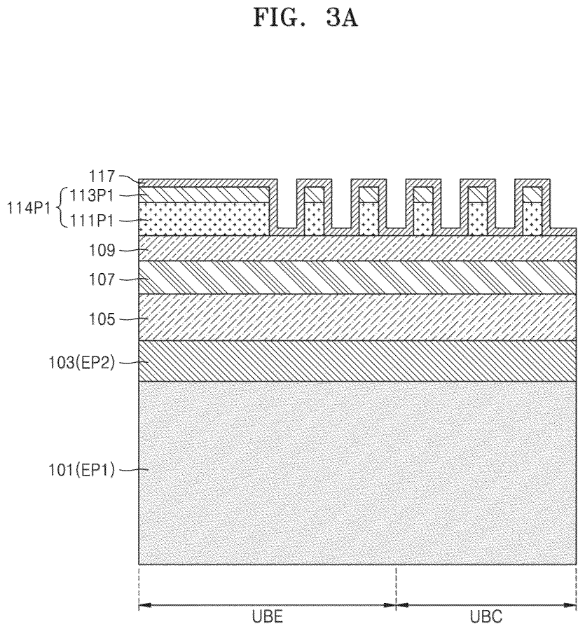

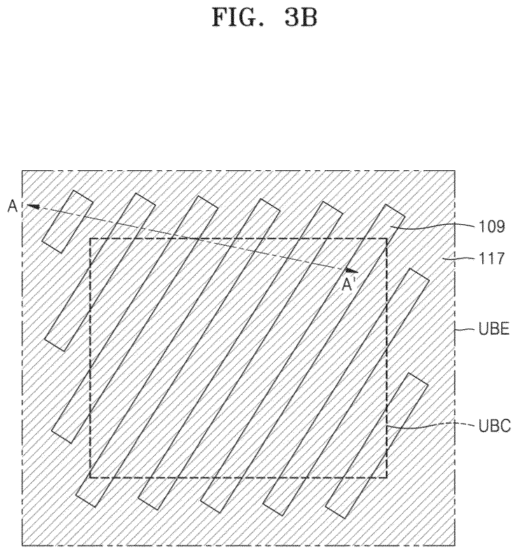

Referring to FIGS. 3A and 3B, a plurality of sacrificial patterns 114P1 spaced apart from each other are formed by patterning the sacrificial layer 114 of FIG. 2A, where sacrificial patterns 114P1 can include a first sacrificial pattern 111P1 and a second sacrificial pattern 113P1. The plurality of sacrificial patterns 114P1 can be formed by patterning the sacrificial layer 114 using a photolithography process. A first sacrificial pattern 111P1 and a second sacrificial pattern 113P1 may be formed by removing parts of the first sacrificial layer 111 and the second sacrificial layer 113, respectively. A plurality of sacrificial patterns spaced apart from each other on the second hard mask layer of the cell edge region can be formed simultaneously, and a plurality of first spacers spaced apart from each other can be formed on the second hard mask layer of the cell center region simultaneously with the plurality of sacrificial patterns.

An etch process for etching the sacrificial layer 114 may use a dry etch or a reactive ion etch (RIE). Widths of the sacrificial patterns 114P1 may be different from each other. For example, widths of some of the sacrificial patterns 114P1 formed on the cell edge region UBE may be greater than widths of the sacrificial patterns 114P1 formed on the cell center region UBC.

In various embodiments, a first spacer insulating layer 117 is formed on the sacrificial patterns 114P1 of the cell center region UBC and the cell edge region UBE, where the first spacer insulating layer 117 can be formed on the exposed surfaces of the sacrificial patterns 114P1. The first spacer insulating layer 117 may be formed on sidewalls and upper surfaces of the sacrificial patterns 114P1 and on the surface of the third hard mask layer 109. The first spacer insulating layer 117 may cover exposed upper surfaces of the sacrificial patterns 114P1 and the third hard mask layer 109. As shown in FIG. 3B, the first spacer insulating layer 117 may be formed on the entire surface of the second sacrificial pattern 113P1.

The first spacer insulating layer 117 may include a material having etch selectivity with regard to the sacrificial patterns 114P1. In some embodiments, the first spacer insulating layer 117 may include the same material as at least a part of the third hard mask layer 109. In some embodiments, the first spacer insulating layer 117 may include silicon oxide or silicon oxynitride. The first spacer insulating layer 117 can include a material layer having an etch selectivity compared to the plurality of second center hard mask patterns 107P2.

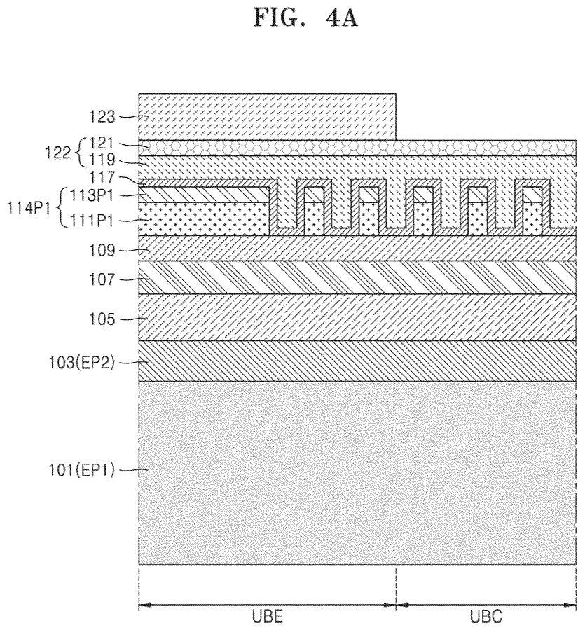

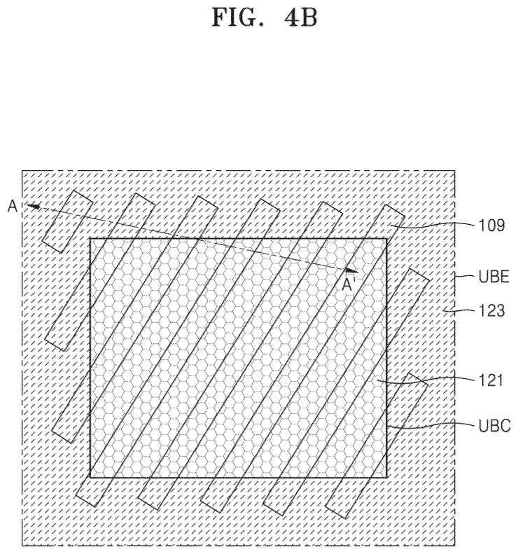

Referring to FIGS. 4A and 4B, a protection layer 122 is formed on the first spacer insulating layer 117 in the cell center region UBC and the cell edge region UBE. The protection layer 122 may be formed on the first spacer insulating layer 117 on the sacrificial patterns 114P1 of the cell center region UBC and the cell edge region UBE.

In various embodiments, the protection layer 122 may include a first protection layer 119 and a second protection layer 121. The first protection layer 119 may be formed to fill spaces between adjacent portions of the sacrificial patterns 114P1 in the cell center region UBC and the cell edge region UBE. The second protection layer 121 may be formed on the first protection layer 119. The first protection layer 119 may include a carbon-containing material, such as SOH, and the second protection layer 121 may include silicon oxynitride (SiON).

A second photoresist pattern 123 exposing the cell center region UBC may be formed on the second protection layer 121 of the protection layer 122. The second photoresist pattern 123 may be formed on the cell edge region UBE by forming a photoresist material layer on the entire surface of the cell center region UBC, the cell edge region UBE, and the peripheral circuit region PPCR of FIG. 1 through the photolithography process. As shown in FIG. 4B, the second photoresist pattern 123 may be formed only in the cell edge region UBE, and the surface of the second protection layer 121 may be exposed in the cell center region UBC.

Referring to FIGS. 5A and 5B, the first spacers 117P2 can be formed in the cell center region UBC by etching the protection layer 122 and the first spacer insulating layer 117 of the cell center region UBC utilizing the second photoresist pattern 123 of FIGS. 4A and 4B as an etch mask. The second photoresist pattern 123 can protect the cell edge region UBE during etching of the cell center region UBC, and subsequently removed. The upper surface of the first spacer insulating layer 117 can be exposed by removal of the second protection layer 121 and the first protection layer 119. The surfaces of the first spacer insulating layer 117 parallel to the surface of third hard mask layer 109 can be subsequently removed by etching to form the first spacers 117P2 on the sacrificial patterns 114P1 and expose the second sacrificial pattern 113P1.

The sacrificial patterns 114P1 of FIG. 4A may be removed after forming the first spacers 117P2 on the sidewalls of the sacrificial patterns 114P1 in the cell center region UBC. As shown in FIG. 5B, the first spacers 117P2 may be disposed on both sides of the third hard mask layer 109 in the cell center region UBC. The first spacers 117P2 can be continuous and surround a region of the third hard mask layer 109.

The first spacers 117P2 may be formed by etching the first spacer insulating layer 117 of FIG. 4A until the third hard mask layer 109 between the sacrificial patterns 114P1 of the cell center region UBC is exposed. The first spacers 117P2 may be used as an etch mask for increasing a pattern density in a subsequent process. Accordingly, thicknesses of the first spacers 117P2 may be determined in consideration of sizes and pitches of the etch patterns ETP of FIG. 1 or patterns to be formed.

According to etching of the protection layer 122 and the first spacer insulating layer 117 of the cell center region UBC by using the second photoresist pattern 123 as an etch mask, the protection layer 122 and the first spacer insulation layer 117 of the cell edge region UBE can form the protection pattern 122P1 and the first spacer insulating pattern 117P1, respectively. The protection pattern 122P1 may include a first protection pattern 119P1 and a second protection pattern 121P1.

The first protection pattern 119P1 may be formed to fill between the sacrificial patterns 114P1 of the cell edge region UBE, where the first protection pattern 119P1 can be formed on the inner walls and the surfaces of the plurality of sacrificial patterns 114P1. The second protection pattern 121P1 may be formed on the first protection pattern 119P1.

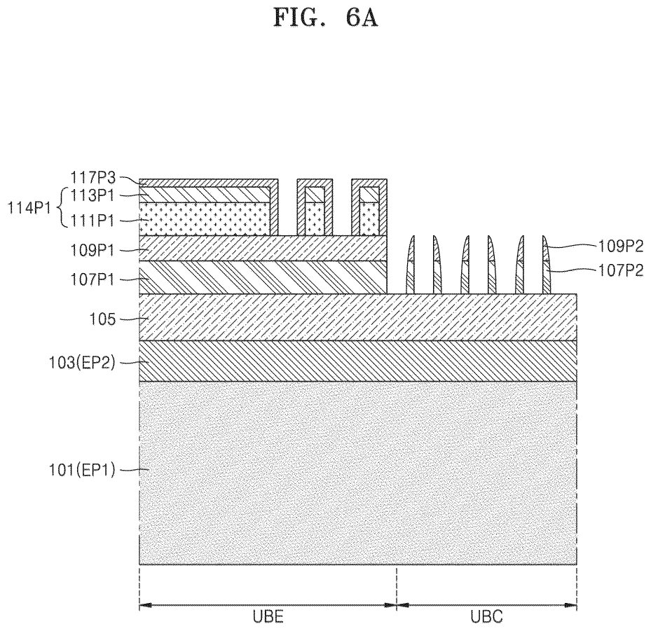

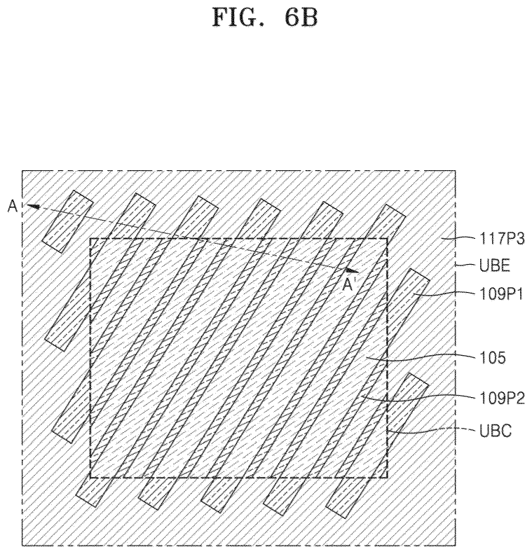

Referring to FIGS. 6A and 6B, the third hard mask layer 109 and the second hard mask layer 107 of the cell center region UBC can be etched by using the protection pattern 122P1 of FIG. 5A of the cell edge region UBE and the first spacers 117P2 of the cell center region UBC as an etch mask.

In various embodiments, a second edge hard mask pattern 107P1 and a third edge hard mask pattern 109P1 may be formed on the cell edge region UBE. At the same time, second center hard mask patterns 107P2 and third center hard mask patterns 109P2 may be formed on the cell center region UBC. The second edge hard mask pattern 107P1 can be formed on the cell edge region UBE simultaneously with a plurality of second center hard mask patterns 107P2 spaced apart from each other on the cell center region UBC by etching the second hard mask layer 107 using the protection pattern 122P1 and the plurality of first spacers 117P2 as an etch mask.

The third center hard mask patterns 109P2 may or may not partially remain on the second center hard mask patterns 107P2. As shown in FIG. 6B, the third center hard mask patterns 109P2 may be disposed on both sides of the first hard mask layer 105 in the cell center region UBC. When the third center hard mask patterns 109P2 are removed, the second center hard mask patterns 107P2 may be disposed on both sides of the first hard mask layer 105. The third center hard mask patterns 109P2 and second center hard mask patterns 107P2 can be continuous and surround a region of the first hard mask layer 105.

Subsequently, the protection pattern 122P1 of FIG. 5A of the cell edge region UBE may be etched and removed. When the protection pattern 122P1 is removed, the first spacer insulating pattern 117P1 formed on the third edge hard mask pattern 109P1 between the sacrificial patterns 114P1 of the cell edge region UBE may be etched, so that the second spacer insulating pattern 117P3 may be formed. In some embodiments, the first spacer insulating pattern 117P1 may be wholly etched so that the second spacer insulating pattern 117P3 may not be formed.

The manufacturing process of FIGS. 2A to 6B may correspond to a double patterning technology (DPT) of forming two second center hard mask patterns 107P2 from one sacrificial pattern 114P1 in the cell center region UBC.

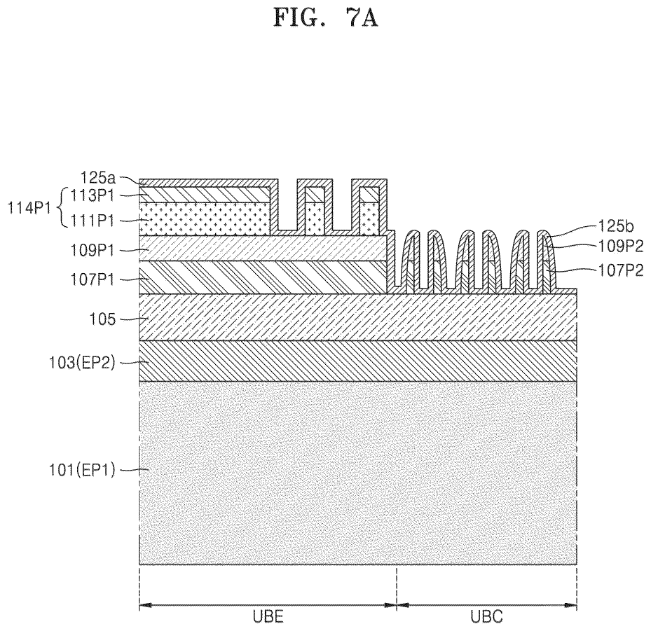

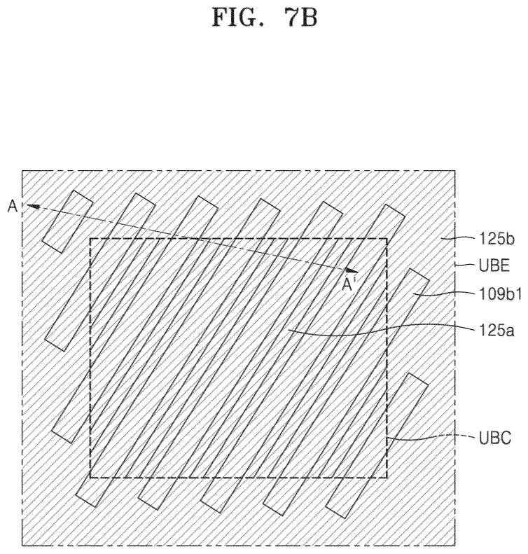

Referring to FIGS. 7A and 7B, a separation insulating layer 125a and a second spacer insulating layer 125b can be formed in the cell edge region UBE and the cell center region UBC, respectively. The separation insulating layer 125a and the second spacer insulating layer 125b may be formed in the same process. The separation insulating layer 125a and the second spacer insulating layer 125b may include silicon oxide or silicon oxynitride.

As shown in FIG. 7B, the separation insulating layer 125a and the second spacer insulating layer 125b may be formed on the entire surface of the cell edge region UBE and the cell center region UBC. The separation insulating layer 125a may be formed on the sacrificial patterns 114P1 and the third edge hard mask pattern 109P1 in the cell edge region UBE. The separation insulating layer 125a may be a separation pattern used to remove the sacrificial patterns 114P1 in a subsequent process.

The second spacer insulating layer 125b may be formed on the third center hard mask pattern 109P2, the second center hard mask patterns 107P2, and the first hard mask layer 105 in the cell center region UBC. The second spacer insulating layer 125b may become second spacers in a subsequent process.

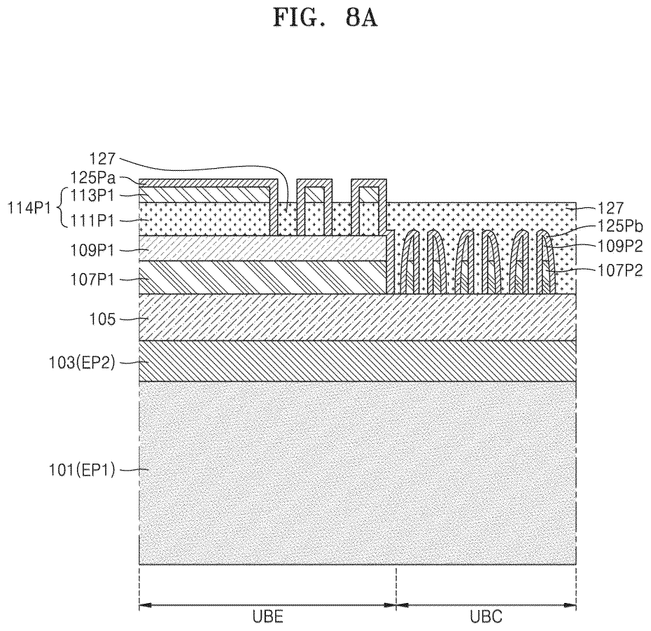

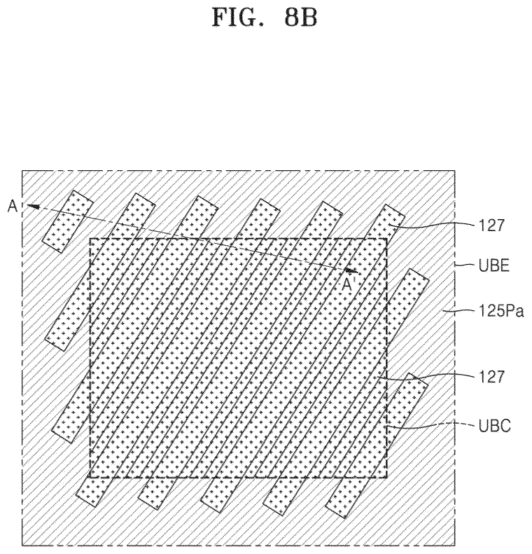

Referring to FIGS. 8A and 8B, a first separation pattern 125Pa can be formed by etching the separation insulating layer 125a formed between the sacrificial patterns 114P1 on the third edge hard mask pattern 109P1 in the cell edge region UBE. A second spacer insulating pattern 125Pb can be formed by etching the second spacer insulating layer 125b formed between the second center hard mask patterns 107P2 on the first hard mask layer 105 in the cell center region UBC. Etching of the separation insulating layer 125a and etching of the second spacer insulating layer 125b may be performed in the same process. Etching of the separation insulating layer 125a and etching of the second spacer insulating layer 125b may use a dry or wet etch process.

Subsequently, a filling layer 127 can be formed between the sacrificial patterns 114P1 on the third edge hard mask pattern 109P1 in the cell edge region UBE and between the second center hard mask patterns 107P2 on the first hard mask layer 105 in the cell center region UBC.

In various embodiments, a surface of the filling layer 127 and a surface of the first sacrificial pattern 111P1 may be coplanar. The filling layer 127 may include the same material as the first sacrificial pattern 111P1. The filling layer 127 may include a carbon-containing material, such as SOH. As shown in FIG. 8B, the filling layer 127 may be formed in the cell center region UBC, and the filling layer 127 and the first separation pattern 125Pa may be disposed on the cell edge region UBE. The filling layer 127 can cover the surfaces in the cell center region UBC, while portions of the first separation pattern 125Pa can remain exposed in the cell edge region UBE.

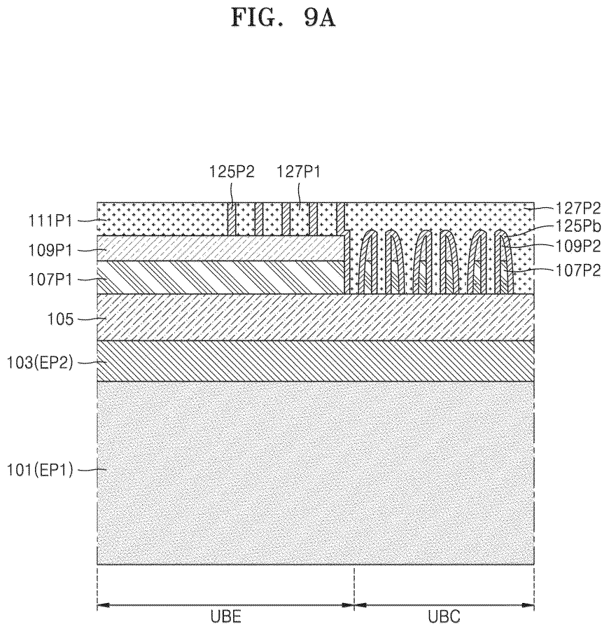

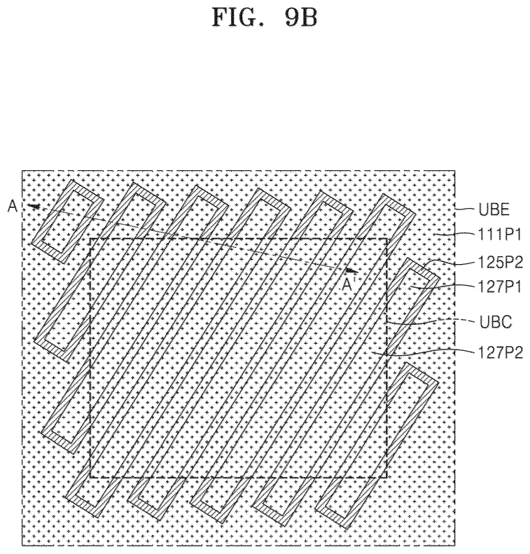

Referring to FIGS. 9A and 9B, the first separation pattern 125Pa of FIG. 8A and the second sacrificial pattern 113P1 of FIG. 8A of the cell edge region UBE can be etched. The first separation pattern 125Pa and the second sacrificial pattern 113P1 of FIG. 8A in the cell edge region UBE can be planarized and etched with respect to a surface of the filling layer 127 of the cell edge region UBE and the cell center region UBC.

Accordingly, the first sacrificial pattern 111P1, first filling patterns 127P1, and second separation patterns 125P2 between the first filling patterns 127P1 may be formed on the second edge hard mask pattern 109P1 in the cell edge region UBE. A surface of the second separation pattern 125P2, the first filling pattern 127P1 and a second filling pattern 127P2 may be coplanar.

In various embodiments, the second center hard mask patterns 107P2 and the third center hard mask patterns 109P2 may be disposed on the first hard mask layer 105 in the cell center region UBC, where the second filling pattern 127P2 can cover the second spacer insulating pattern 125Pb on the second center hard mask patterns 107P2 and the third center hard mask patterns 109P2. The second filling pattern 127P2 may be formed between the second center hard mask patterns 107P2 and the third center hard mask patterns 109P2 of the cell center region UBC.

As shown in FIG. 9B, the first filling pattern 127P1, the second separation pattern 125P2, and the first sacrificial pattern 111P1 may be disposed on the cell edge region UBE, and the second filling pattern 127P2 may be disposed on the cell center region UBC. The second filling pattern 127P2 can cover the surfaces in the cell center region UBC.

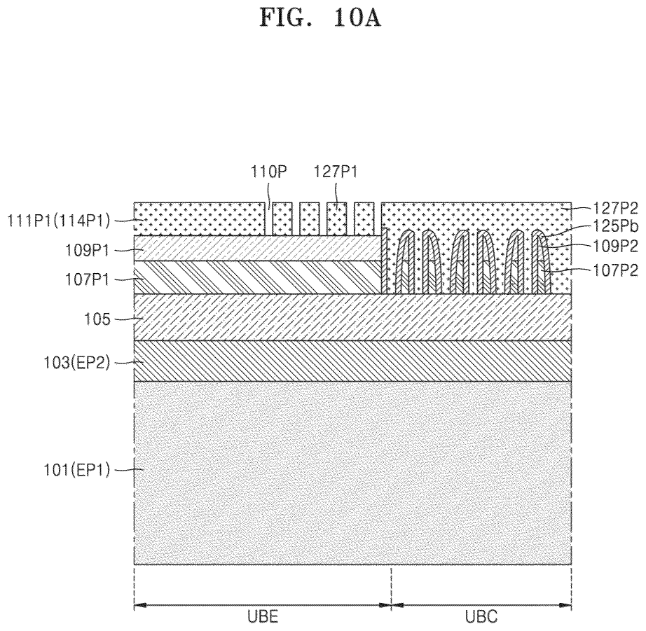

Referring to FIGS. 10A and 10B, the second separation pattern 125P2 of FIG. 9A disposed on the second edge hard mask pattern 109P1 of the cell edge region UBE can be removed. The second separation pattern 125P2 disposed between the first filling patterns 127P1 of the cell edge region UBE can be removed to form an opening pattern 110P in the cell edge region UB.

The opening pattern 110P may be formed between the first filling patterns 127P1 on the second edge hard mask pattern 109P1 of the cell edge region UBE, where portions of the second edge hard mask pattern 109P1 can be exposed in the opening pattern 110P. As shown in FIG. 10B, the first filling pattern 127P1, the opening pattern 110P, and the first sacrificial pattern 111P1 may be disposed in the cell edge region UBE, and the second filling pattern 127P2 may be disposed on the cell center region UBC.

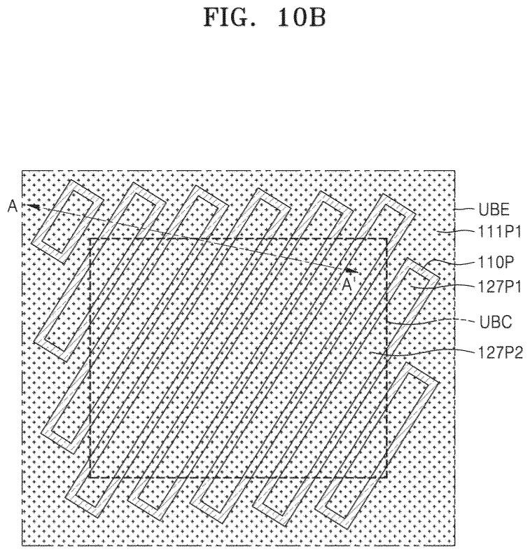

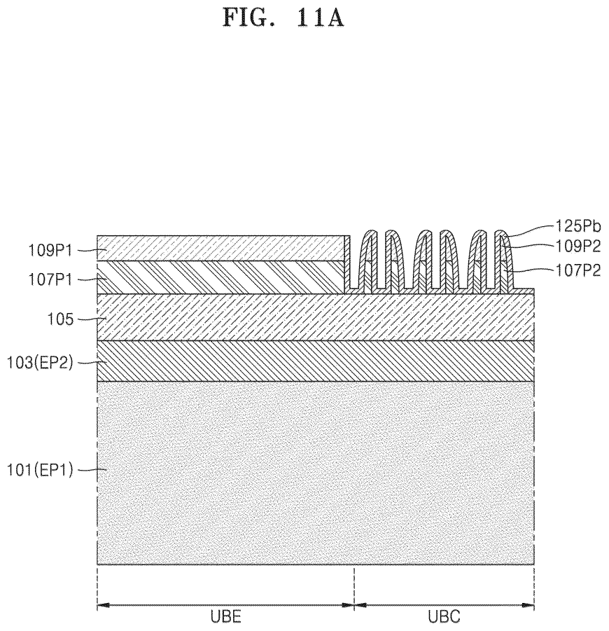

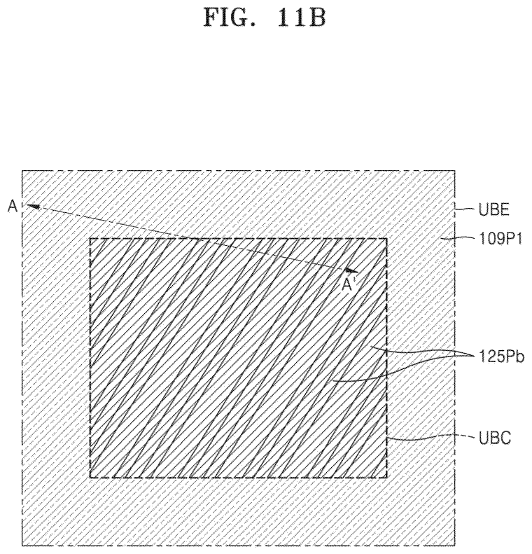

Referring to FIGS. 11A and 11B, the first sacrificial pattern 111P1 and the first filling pattern 127P1 of FIG. 10A of the cell edge region UBE can be removed using an etch process. The second filling pattern 127P2 of the cell center region UBC can be removed using an etch process. The first sacrificial pattern 111P1 and the first filling pattern 127P1 of FIG. 10A of the cell edge region UBE and the second filling pattern 127P2 of the cell center region UBC may be removed by the same etch process.

In various embodiments, the first sacrificial pattern 111P1 and the first filling pattern 127P1 may be removed without damaging the cell edge region UBE, and the second edge hard mask pattern 109P1 may be exposed, as shown for example in FIG. 11A. The second spacer insulating pattern 125Pb may be exposed in the cell center region UBC. As shown in FIG. 11B, the second edge hard mask pattern 109P1 may cover the surfaces in the cell edge region UBE, and the second spacer insulating pattern 125Pb may cover the surfaces in the cell center region UBC.

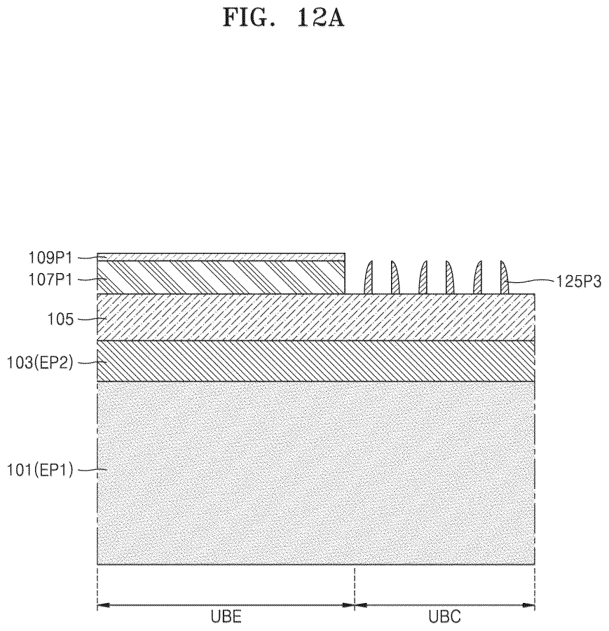

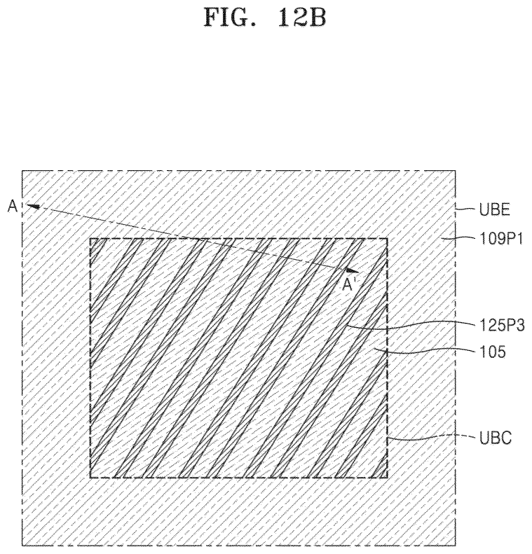

Referring to FIGS. 12A and 12B, second spacers 125P3 can be formed on the first hard mask layer 105 by etching the second spacer insulating pattern 125Pb of FIG. 11A of the cell center region UBC. The second spacers 125P3 may be formed by forming the second spacer insulating pattern 125Pb of FIG. 11A as a material layer having an etch selectivity compared to the second center hard mask patterns 107P2. When the second spacers 125P3 are formed, a thickness of the second edge hard mask pattern 109P1 formed on the cell edge region UBE may be reduced. A plurality of second spacers 125P3 spaced apart from each other can be formed simultaneously by etching the second spacer insulating layer 125b and removing the plurality of second center hard mask patterns 107P2 between the plurality of second spacers 125P3.

As shown in FIG. 12B, the first hard mask layer 105 and the second spacers 125P3 may be on the cell center region UBC. The third edge hard mask pattern 109P1 may be on the cell edge region UBE.

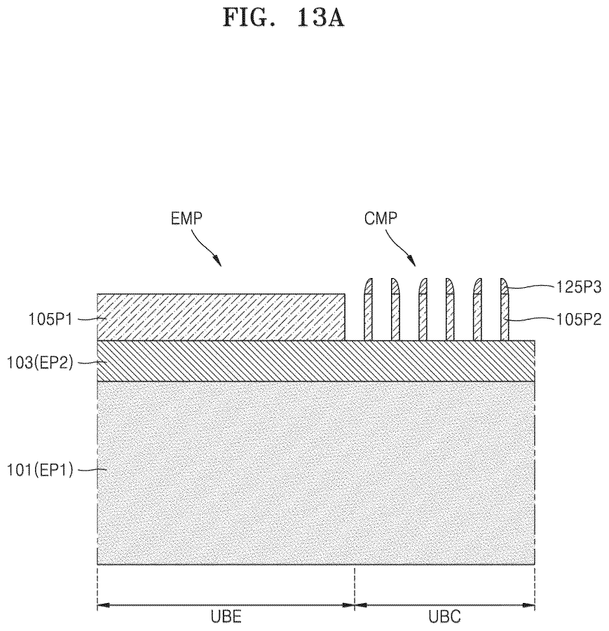

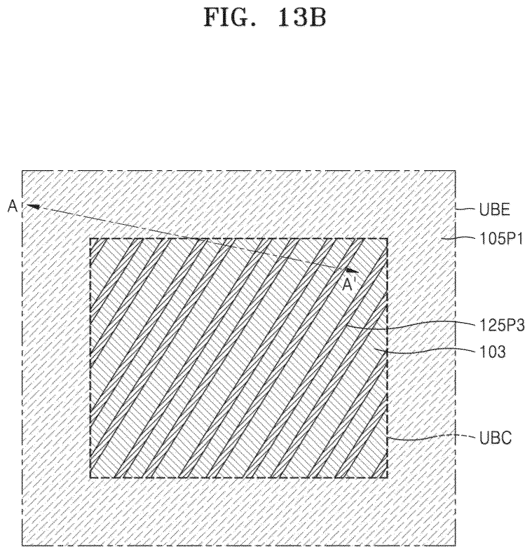

Referring to FIGS. 13A and 13B, the first hard mask layer 105 of FIG. 12A can be etched by using the third edge hard mask pattern 109P1 and the second edge hard mask pattern 107P1 of the cell edge region UBE, and the second spacers 125P3 of the cell center region UBC as an etch mask.

In various embodiments, the first edge hard mask pattern 105P1 may be formed on the pad insulating layer 103 of the cell edge region UBE. The first edge hard mask pattern 105P1 may be an edge mask pattern EMP. An edge mask pattern EMP can be formed on the cell edge region by etching the first hard mask layer 105 using the second edge hard mask pattern 107P1 as an etch mask, while simultaneously forming a plurality of center mask patterns CMP spaced apart from each other on the cell center region UBC using the plurality of second spacers 125P3 as an etch mask.

The first center hard mask patterns 105P2 may be formed on the pad insulating layer 103 of the cell center region UBC. The first center hard mask patterns 105P2 may include a plurality of patterns spaced apart from each other. The first center hard mask patterns 105P2 may be center mask patterns CMP. The center mask patterns CMP may include a plurality of patterns spaced apart from each other. A width of the edge mask pattern EMP may be larger than a width of each of the center mask patterns CMP in a cross section.

When the first hard mask layer 105 of FIG. 12A is etched, some of the second spacers 125P3 may remain on the first center hard mask pattern 105P2 of the cell center region UBC, where the second spacers 125P3 may have a different etch selectivity from the first hard mask 105. As shown in FIG. 13B, the second spacers 125P3 and the pad insulating layer 103 may be in the cell center region UBC, and the first edge hard mask pattern 105P1 may be on the cell edge region UBE.

Through the above manufacturing process, in the inventive concept, the edge mask pattern EMP and the center mask patterns CMP may be formed only in the cell region CELR of FIG. 1 by forming a plurality of hard mask layer on the entire surface of the cell region CELR, including the cell edge region UBE and the cell center region UBC and the peripheral circuit region PPCR of FIG. 1, and patterning the hard mask layers.

The manufacturing process of FIGS. 7A to 13B may correspond to a DPT of forming two first center hard mask patterns 105P2 from one second center hard mask pattern 107P2 in the cell center region UBC. As a result, the manufacturing process of FIGS. 2A to 13B may correspond to a quadruple patterning technology (QPT) of forming four first center hard mask patterns 105P2 from one sacrificial pattern 114P1. An edge mask pattern EMP may be formed on a surface of the cell edge region UBE through a quadruple patterning process on the etch target layer EP2 or EP1. A plurality of center mask patterns spaced apart from each other may be formed by the quadruple patterning process on the cell center region.

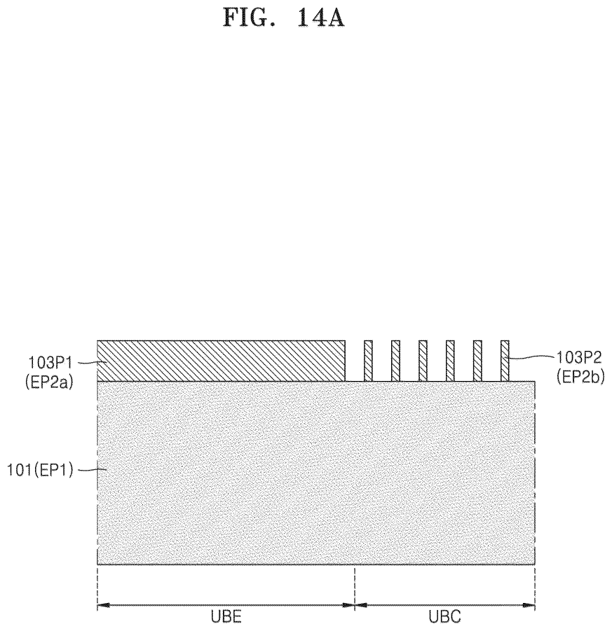

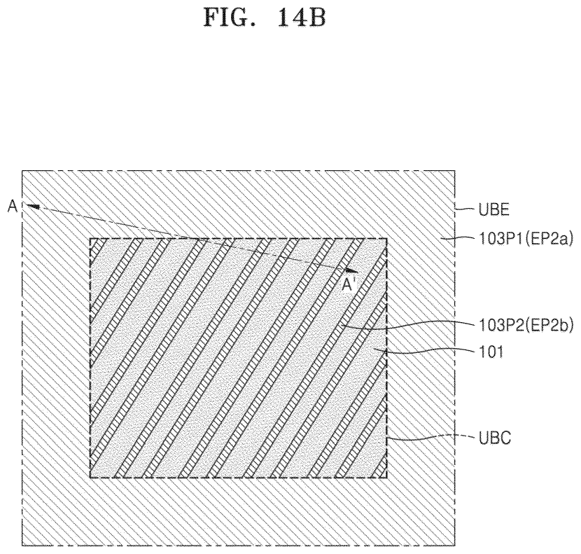

Referring to FIGS. 14A and 14B, the pad insulating layer 103 may be etched by using the first edge hard mask pattern 105P1 of FIG. 13A of the cell edge region UBE and the first center hard mask pattern 105P2 of FIG. 13A of the cell center region UBC as an etch mask.

In this case, a first pad insulating pattern 103P1 may be formed on the cell edge region UBE, and a second pad insulating pattern 103P2 may be formed on the cell center region UBC. The second pad insulating pattern 103P2 may include a plurality of sub pad insulating patterns spaced apart from each other. As shown in FIG. 14B, the second pad insulating pattern 103P2 and the semiconductor substrate 101 may be on the cell center region UBC, and the first pad insulating pattern 103P1 may be on the cell edge region UBE.

As described above, when the pad insulating layer 103 of FIG. 13A is referred to as the second etch target layer EP2, the first pad insulating pattern 103P1 and the second pad insulating pattern 103P2 may be respectively referred to as a third etch pattern EP2a and fourth etch patterns EP2b. The fourth etch patterns EP2b may include a plurality of patterns spaced apart from each other. As shown in FIG. 14B, the fourth etch patterns EP2b may be inclined on the semiconductor substrate 101 of FIG. 14A, that is, in a diagonal direction, in a plan view.

Referring to FIGS. 15A and 15B, unlike the description of FIGS. 14A and 14B, the pad insulating layer 103 and the semiconductor substrate 101 may be sequentially etched by using the first edge hard mask pattern 105P1 of FIG. 13A of the cell edge region UBE and the first center hard mask patterns 105P2 of FIG. 13A of the cell center region UBC as an etch mask. A first etch pattern EP1a can be formed on the cell edge region UBE by etching the etch target layers EP1 and EP2 using the edge mask pattern EMP and the plurality of center mask patterns CMP as etch masks, and forming a plurality of second etch patterns EP1b spaced apart from each other on the cell center region UBC.

In various embodiments, a first active pattern 101P1 may be formed on the cell edge region UBE, and second active patterns 101P2 may be formed on the cell center region UBC. The second active patterns 101P2 may include a plurality of patterns spaced apart from each other. Trench patterns 101P3 may be formed between adjacent pairs of the second active patterns 101P2. As shown in FIG. 15B, the second active patterns 101P2 and the trench patterns 101P3 may be disposed on the cell center region UBC, and the first active pattern 101P1 may be disposed on the cell edge region UBE.

The pad insulating layer 103 may partly remain or may be entirely removed when the pad insulating layer 103 and the semiconductor substrate 101 are sequentially etched by using the first edge hard mask pattern 105P1 of FIG. 13A of the cell edge region UBE and the first center hard mask patterns 105P2 of FIG. 13A of the cell center region UBC as an etch mask. FIGS. 15A and 15B do not illustrate the pad insulating layer 103 for convenience.

As described above, when the semiconductor substrate 101 of FIG. 14A is referred to as the first etch target layer EP1 of FIG. 14A, the first active pattern 101P1 and the second active pattern 101P2 may be respectively referred to as the first etch pattern EP1a and second etch patterns EP1b. The second etch patterns EP1b may include a plurality of patterns separated from each other.

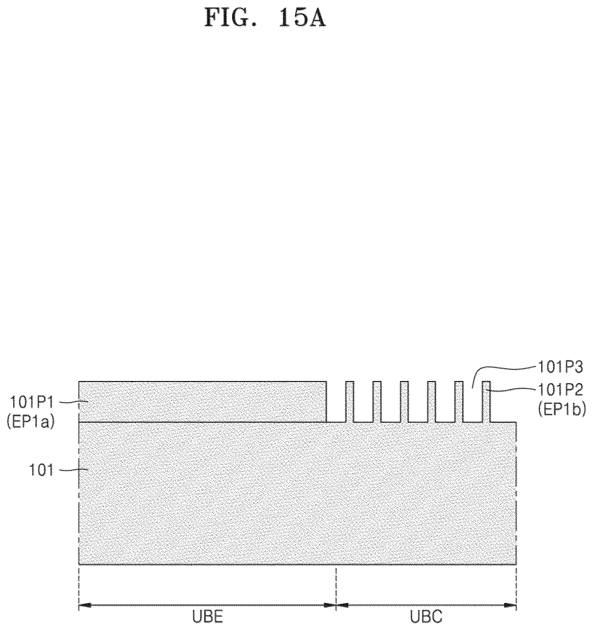

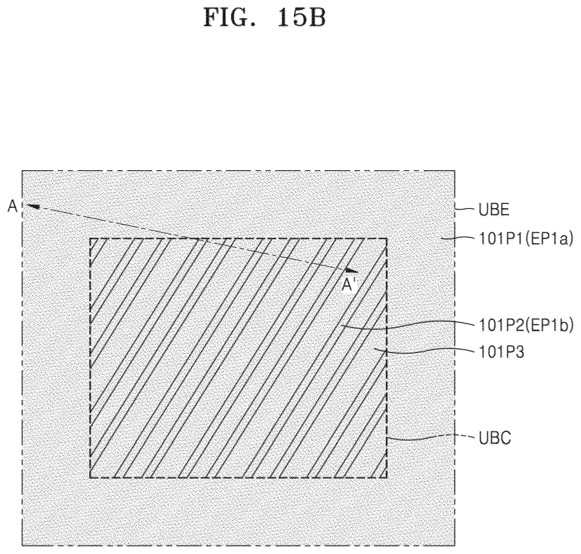

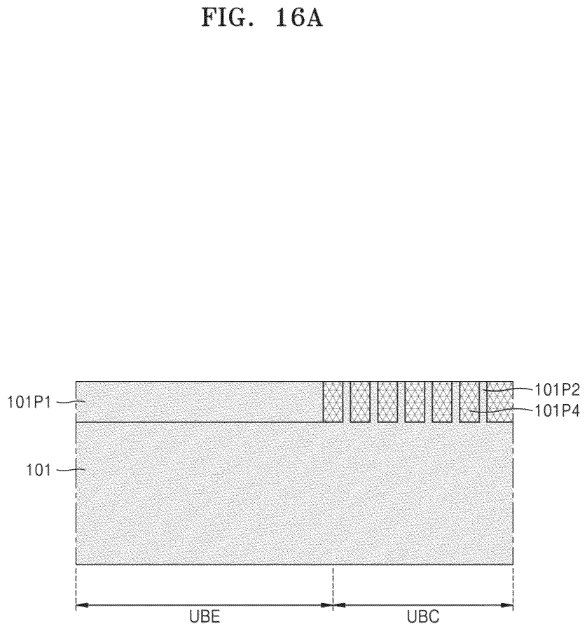

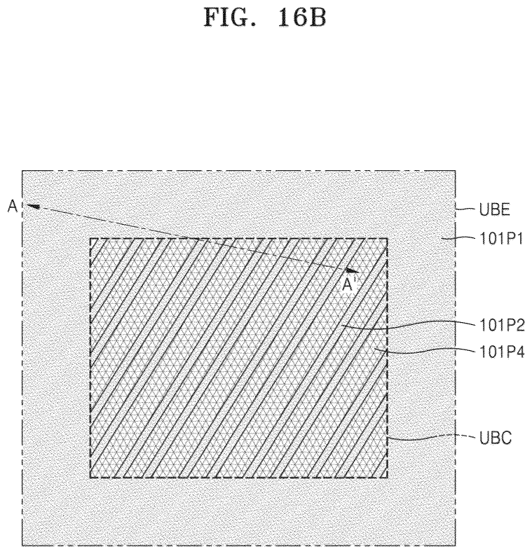

Referring to FIGS. 16A and 16B, a trench insulating pattern 101P4 may be formed on the trench pattern 101P3 of the cell center region UBC of FIGS. 15A and 15B. The trench insulating pattern 101P4 may be a device separation insulating layer, where the trench insulating pattern 101P4 can fill the trench patterns 101P3 formed between adjacent pairs of the second active patterns 101P2.

In various embodiments, the first active pattern 101P1 may be formed on the cell edge region UBE, and the second active patterns 101P2 electrically separated by the trench insulating pattern 101P4 may be formed on the cell center region UBC. The second active patterns 101P2 may include a plurality of patterns spaced apart from each other. As shown in FIG. 16B, the second active patterns 101P2 and the trench insulating pattern 101P4 may be disposed on the cell center region UBC, and first active pattern 101P1 may be disposed on the cell edge region UBE.

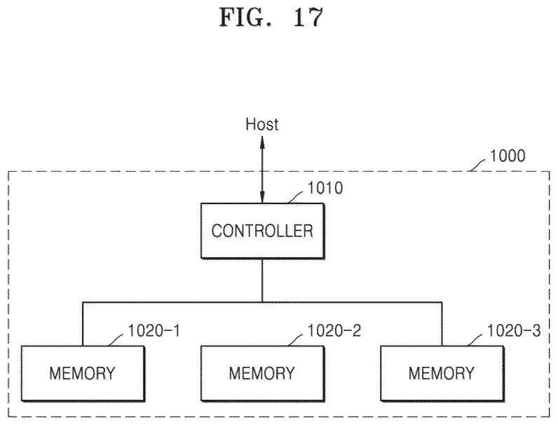

FIG. 17 is a block diagram illustrating a storage device including a semiconductor device according to an embodiment.

Specifically, a storage device 1000 according to the present embodiment may include a controller 1010 communicating with a host HOST and memories 1020-1, 1020-2, and 1020-3 that may each store data. On or more of the memories 1020-1, 1020-2, and 1020-3 may include a semiconductor device manufactured by using the method of manufacturing the semiconductor device according to an embodiment described above.

The host HOST communicating with the controller 1010 may be various electronic devices in which the storage device 1000 is mounted, and may be, for example, a smart phone, a digital camera, a desktop computer, a laptop computer, a media player, etc. The controller 1010 may receive a data write or read request transmitted from the host HOST and store data in the memories 1020-1, 1020-2, the 1020-3, or may generate a command CMD for fetching the data from the memories 1020-1, 1020-2, and 1020-3.

In various embodiments, the one or more memories 1020-1, 1020-2, or 1020-3 in the storage device 1000 may be connected to the controller 1010 in parallel. A storage device 1000 having a large capacity, such as a solid state drive (SSD), may be implemented utilizing a plurality of memories 1020-1, 1020-2, and 1020-3 that are connected to the controller 1010 in parallel.

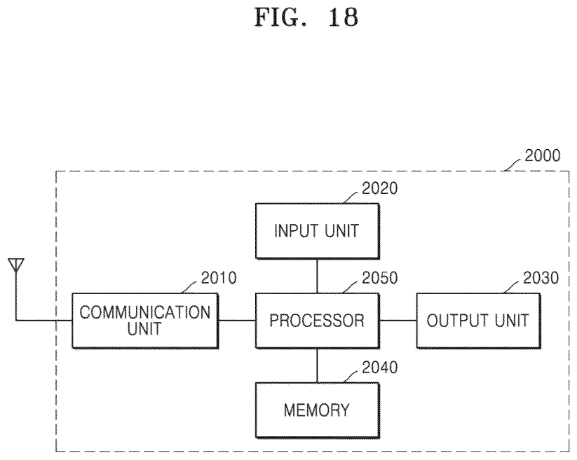

FIG. 18 is a block diagram illustrating an electronic device including a semiconductor device according to an embodiment.

Specifically, an electronic device 2000 according to an embodiment may include a communication unit 2010, an input unit 2020, an output unit 2030, a memory 2040, and a processor 2050.

The communication unit 2010 may include a wired/wireless communication module, and may include a wireless Internet module, a short distance communication module, a GPS module, a mobile communication module, etc. The wired/wireless communication module included in the communication unit 2010 may be connected to an external communication network according to various communication standards to transmit/receive data.

The input unit 2020 is a module provided for a user to control an operation of the electronic device 2000, and may include a mechanical switch, a touch screen, a speech recognition module, etc. In addition, the input unit 2020 may include a mouse operating in a track ball or a laser pointer method, or a finger mouse device, and may further include various sensor modules through which the user may input data.

The output unit 2030 may output information processed by the electronic device 2000 in the form of audio and/or video, and the memory 2040 may store programs for processing and control of the processor 2050 or data. The memory 2040 may include one or more semiconductor devices manufactured by using the method of manufacturing a semiconductor device according to an embodiment described above. The processor 2050 may transfer instructions to the memory 2040 and/or retrieve instructions from the memory 2040, according to necessary operations to store or retrieve data.

The memory 2040 may be embedded in the electronic device 2000 or may communicate with the processor 2050 through a separate interface. When the memory 2040 communicates with the processor 2050 through a separate interface, the processor 2050 may store or retrieve data in or from the memory 2040 through various interface standards such as SD, SDHC, SDXC, MICRO SD, and USB.

The processor 2050 can control the operation of each unit included in the electronic device 2000. The processor 2050 may perform control and processing related to voice calls, video calls, and data communications, or control and processing for multimedia reproduction and management. Also, the processor 2050 may process input transmitted from the user through the input unit 2020 and output a result of processing through the output unit 2030. Also, as described above, the processor 2050 may store data necessary for controlling the operation of the electronic device 2000 in the memory 2040 and/or retrieve the data from the memory 2040.

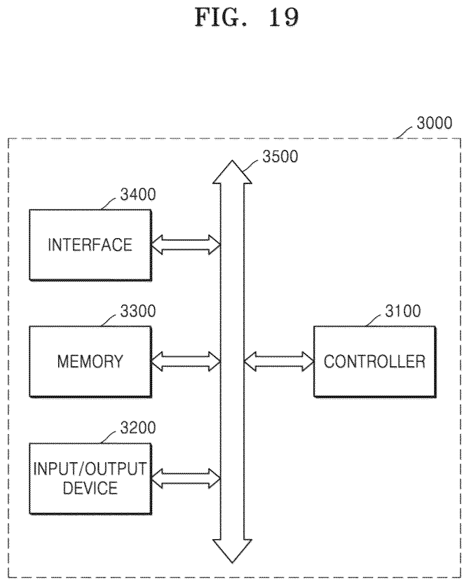

FIG. 19 is a schematic diagram illustrating a system including a semiconductor device according to an embodiment.

Specifically, a system 3000 may include a controller 3100, an input/output device 3200, a memory 3300, and an interface 3400. The system 3000 may be a mobile system or a system that transmits or receives information. The mobile system may be a PDA, a portable computer, a web tablet, a wireless phone, a mobile phone, a digital music player or a memory card.

The controller 3100 may serve to execute programs and control the system 3000. The controller 3100 may be, for example, a microprocessor, a digital signal processor, a microcontroller, or a similar device.

The input/output device 3200 may be used to input or output data of the system 3000. The system 3000 may be connected to an external device, such as a personal computer or a network, by using the input/output device 3200, to exchange data with the external device. The input/output device 3200 may be, for example, a keypad, a keyboard, or a display.

The memory 3300 may store codes and/or data for an operation of the controller 3100 and/or store data processed by the controller 3100. The memory 3300 may include a non-volatile memory according to any one of the embodiments.

The interface 3400 may be a data transmission path between the system 3000 and another external device. The controller 3100, the input/output device 3200, the memory 3300, and the interface 3400 may communicate with each other through a bus 3500. At least one of the controller 3100 or the memory 3300 may include one or more semiconductor devices manufactured by using the method of manufacturing a semiconductor device according to an embodiment described above.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming an etch target layer within a cell region comprising a cell center region and a cell edge region surrounding the cell center region;
forming an edge mask pattern on a surface of the cell edge region through a quadruple patterning process on the etch target layer, and forming a plurality of center mask patterns spaced apart from each other on the cell center region; and
forming a first etch pattern on the cell edge region by etching the etch target layer using the edge mask pattern and the plurality of center mask patterns as etch masks, and forming a plurality of second etch patterns spaced apart from each other on the cell center region.

2. The method of claim 1, wherein a width of the edge mask pattern is larger than a width of each of the plurality of second etch patterns in a cross section.

3. The method of claim 1, wherein
the etch target layer is formed as a semiconductor substrate, and
the first etch pattern and the plurality of second etch patterns are formed as active patterns.

4. The method of claim 1, wherein
the etch target layer is formed as a semiconductor substrate, and
the plurality of second etch patterns are inclined on the semiconductor substrate in a plan view.

5. The method of claim 1, wherein the edge mask pattern and the plurality of center mask patterns are formed as hard mask patterns.

6. The method of claim 1, wherein a peripheral circuit region is around the cell region in a plan view, and includes an interface region formed around the cell edge region and a core region formed around the interface region in a plan view.

7. The method of claim 6, wherein the forming of the edge mask pattern and the plurality of center mask patterns includes:
forming a plurality of hard mask layers on an entire surface of the cell region and the peripheral circuit region; and
forming the edge mask pattern and the plurality of center mask patterns only on the cell region by patterning the plurality of hard mask layers.

8. A method of manufacturing a semiconductor device, the method comprising:
forming an etch target layer on a surface of a cell region comprising a cell center region and a cell edge region surrounding the cell center region;
sequentially forming a first hard mask layer and a second hard mask layer on the etch target layer;
simultaneously forming a plurality of sacrificial patterns spaced apart from each other on the second hard mask layer of the cell edge region and forming a plurality of first spacers spaced apart from each other on the second hard mask layer of the cell center region;
forming a protection pattern on the plurality of sacrificial patterns of the cell edge region and between the plurality of sacrificial patterns;
simultaneously forming a second edge hard mask pattern on the cell edge region and a plurality of second center hard mask patterns spaced apart from each other on the cell center region by etching the second hard mask layer using the protection pattern and the plurality of first spacers as an etch mask;
removing the protection pattern from the cell edge region;
forming a second spacer insulating layer between the plurality of second center hard mask patterns of the cell center region;
simultaneously forming a plurality of second spacers spaced apart from each other by etching the second spacer insulating layer and removing the plurality of second center hard mask patterns between the plurality of second spacers;
simultaneously forming an edge mask pattern on the cell edge region by etching the first hard mask layer using the second edge hard mask pattern as an etch mask and forming a plurality of center mask patterns spaced apart from each other on the cell center region using the plurality of second spacers as an etch mask; and
forming a first etch pattern on the cell edge region by etching the etch target layer by using the edge mask pattern and forming a plurality of second etch patterns spaced apart from each other on the cell center region using the plurality of center mask patterns as an etch mask.

9. The method of claim 8, wherein the second hard mask layer includes a material layer having an etch selectivity compared to a material of the first hard mask layer.

10. The method of claim 8, further comprising: forming a third hard mask layer on the second hard mask layer.

11. The method of claim 8, wherein the protection pattern includes
a first protection pattern formed on inner walls and the surfaces of the plurality of sacrificial patterns, and
a second protection pattern filling between the plurality of sacrificial patterns on the first protection pattern.

12. The method of claim 8, wherein the first spacer insulating layer includes a material layer having an etch selectivity compared to the plurality of second center hard mask patterns.

13. The method of claim 8, wherein
the etch target layer is formed as a semiconductor substrate, and
the first etch pattern and the second etch pattern are formed as active patterns.

14. The method of claim 8, wherein a peripheral circuit region is around the cell region, and
the forming of the edge mask pattern and the plurality of center mask patterns includes
forming a plurality of hard mask layers on an entire surface of the cell region and the peripheral circuit region; and
forming the edge mask pattern and the plurality of center mask patterns only on the cell region by patterning the plurality of hard mask layers.

15. A method of manufacturing a semiconductor device, the method comprising:
forming an etch target layer in an entire surface of a cell region comprising a cell center region and a cell edge region surrounding the cell center region;
sequentially forming a first hard mask layer and a second hard mask layer on the etch target layer;
simultaneously forming a plurality of sacrificial patterns spaced apart from each other on the second hard mask layer of the cell edge region and forming a plurality of first spacers spaced apart from each other on the second hard mask layer of the cell center region;
forming a protection pattern filling inner walls and surfaces of the plurality of sacrificial patterns of the cell edge region and between the plurality of sacrificial patterns;
simultaneously forming a second edge hard mask pattern on the cell edge region by etching the second hard mask layer by using the protection pattern and the plurality of first spacers as an etch mask and forming a plurality of second center hard mask patterns spaced apart from each other on the cell center region;
simultaneously forming a separation pattern between the plurality of sacrificial patterns of the cell edge region and forming a spacer insulating layer between the plurality of second center hard mask patterns of the cell center region;
forming a filling layer filling between the plurality of sacrificial patterns and the plurality of second center hard mask patterns on the separation pattern and the spacer insulating layer;
removing the separation pattern formed between the plurality of sacrificial patterns of the cell edge region;
removing the filling layer of the cell edge region and the cell center region;
simultaneously forming a plurality of second spacers spaced apart from each other by etching the spacer insulating layer between the plurality of second center hard mask patterns and removing the plurality of second center hard mask patterns between the plurality of second spacers;
simultaneously forming an edge mask pattern on the cell edge region by etching the first hard mask layer by using the plurality of second center hard mask patterns and the plurality of second spacers as an etch mask, and forming a plurality of center mask patterns spaced apart from each other on the cell center region; and
forming a first etch pattern on the cell edge region by etching the etch target layer by using the edge mask pattern and the plurality of center mask patterns as an etch mask and forming a plurality of second etch patterns spaced apart from each other on the cell center region.

16. The method of claim 15, wherein the plurality of sacrificial patterns include a first sacrificial pattern and a second sacrificial pattern formed on the first sacrificial pattern.

17. The method of claim 16, wherein a surface of the filling layer and a surface of the first sacrificial pattern are coplanar.

18. The method of claim 15, wherein the protection pattern are formed as a first protection pattern formed on the inner walls and the surfaces of the plurality of sacrificial patterns, and a second protection pattern filling between the plurality of sacrificial patterns on the first protection pattern.

19. The method of claim 15, wherein a surface of the separation pattern is coplanar with a surface of the filling layer.

20. The method of claim 15, wherein
the etch target layer is configured as a semiconductor substrate, and
the first etch pattern and the plurality of second etch patterns are formed as active patterns.
